(19) United States
(12) Patent Application Publication
(10) Pub. No.: US 2014/0251670 A1
(43) Pub. Date: Sep. 11, 2014

(54) MODULE, METHOD FOR MANUFACTURING THE MODULE, AND ELECTRONIC APPARATUS INCLUDING THE MODULE

(71) Applicant: Murata Manufacturing Co., Ltd., Kyoto-fu (JP)

(72) Inventors: Norio SAKAI, Kyoto-fu (JP); Yoshihito OTSUBO, Kyoto-fu (JP)

(73) Assignee: Murata Manufacturing Co., Ltd., Kyoto-fu (JP)

(21) Appl. No.: 14/200,743

(22) Filed: Mar. 7, 2014

(30) Foreign Application Priority Data
Mar. 8, 2013 (JP) 2013-046237

(51) Int. Cl. H05K 1/18; H05K 3/30

(52) U.S. Cl. CPC H05K 1/18; H05K 3/30
USPC 174/260; 29/832

(57) ABSTRACT

A module includes a wiring board; a component mounted on the wiring board; a columnar conductor for external connection, the columnar conductor being connected at one end thereof to the wiring board; and a resin layer disposed on the wiring board and configured to cover the columnar conductor and the component, with an end face of the columnar conductor exposed from a surface of the resin layer, the end face being at the other end of the columnar conductor. A gap to be filled with solder is formed between the resin layer and a periphery of an end portion of the columnar conductor, the end portion being at the other end of the columnar conductor.

### BACKGROUND OF THE INVENTION

1. Field of the Invention

The present invention relates to a module including a wiring board having columnar conductors for external connection, a method for manufacturing the module, and an electronic apparatus including the module.

2. Description of the Related Art

A module such as that illustrated in FIG. 6 is known, which is connected to an external mount board by means of columnar conductors provided on a principal surface of a wiring board on which components are mounted (see, e.g., Japanese Unexamined Patent Application Publication No. 2004-71961 (paragraphs [0023] to [0028], FIG. 1)). Referring to FIG. 6, a module 100 includes a wiring board 101 having wiring electrodes formed on principal surfaces of, and inside, the wiring board 101; a component 102, such as integrated circuits (ICs), mounted on one principal surface of the wiring board 101; a plurality of columnar conductors 103 for external connection, the columnar conductors 103 each being connected at one end thereof to the one principal surface of the wiring board 101; and a resin layer 104 configured to cover the components 102 and the columnar conductors 103.

An end face of each of the columnar conductors 103 at the other end thereof is exposed from a surface of the resin layer 104. To cover the end faces of the columnar conductors 103, external connection terminals 105 are formed on the surface of the resin layer 104. A principal surface of each of the external connection terminals 105 has an area greater than a cross-sectional area of the corresponding columnar conductor 103. By connecting an external mount board 106 and the external connection terminals 105 on the module 100 by means of solder or the like, the module 100 and the mount board 106 are connected together. For connecting the module 100 to the mount board 106, the external connection terminals 105 are formed to increase the connection area, enhance the connection strength, and improve connection reliability between them.

Forming the external connection terminals 105 on the surface of the resin layer 104 increases the height of the module 100 by the thickness of the external connection terminals 105. This makes it difficult to reduce the height of the module 100. A possible solution to this may be to directly connect the columnar conductors 103 to the external mount board 106 without forming the external connection terminals 105. However, due to the recent demand for the reduction in size of the module 100, it is difficult to significantly increase the cross-sectional area of the columnar conductors 103 to improve the connection strength between the module 100 and the mount board 106, and difficult to ensure the desired connection strength by directly connecting the columnar conductors 103 to the mount board 106.

Also, carrying out the process of forming the external connection terminals 105 increases the cost of manufacturing the module 100.

### BRIEF SUMMARY OF THE INVENTION

The present invention has been made to solve the problems described above. An object of the present invention is to provide a module that can achieve a highly reliable connection to an external mount board without providing external connection terminals connected to columnar conductors.

To achieve the object described above, a module according to the present invention is provided, which is externally connected by means of a conductive member. The module includes a wiring board; a component mounted on the wiring board; a columnar conductor for external connection, the columnar conductor being connected at one end thereof to the wiring board; and a resin layer disposed on the wiring board and configured to cover the columnar conductor and the component, with an end face of the columnar conductor exposed from a surface of the resin layer, the end face being at the other end of the columnar conductor. In the module, a gap is formed between the resin layer and at least part of a periphery of an end portion of the columnar conductor, the end portion being at the other end of the columnar conductor.

The gap is formed as described above. Thus, not only the end face but also the at least part of the periphery of the end portion at the other end of the columnar conductor is exposed without being covered with the resin of the resin layer. Both the end face of the columnar conductor and the periphery of the columnar conductor exposed to form the gap, at the other end of the columnar conductor, serve as a connection surface for connection to an external mount board. This makes the connection area greater than that in the case where the module is connected to the mount board only at the end face of the columnar conductor at the other end thereof, and thus improves the connection strength between the module and the mount board. Therefore, without the external connection terminals provided in the related art to ensure the connection strength and connection reliability, it is possible to provide the module that has a highly reliable connection to the mount board.

Since there is no need to provide external connection terminals, it is possible to lower the profile of the module and reduce the cost of manufacture.

The conductive member may be solder, and the gap may be filled with a material having a melting point lower than that of the solder. With this configuration, until the module is connected to an external mount board, the gap is filled with the material having a melting point lower than that of the solder. Therefore, it is possible to prevent dust and impurities from entering the gap before the module is connected to the mount board. During the connection of the module to the mount board, the material is volatilized or melted by heating and moved out of the gap. This facilitates the connection of the module to the mount board.

The columnar conductor may include a first columnar conductor and a second columnar conductor, and a volume of the gap between the resin layer and the first columnar conductor may differ from a volume of the gap between the resin layer and the second columnar conductor. With this configuration, for example, gaps with a small volume may be formed in an area where the columnar conductors are arranged at a high density. This can prevent the solder from flowing and causing the adjacent columnar conductors to be short-circuited when the module is mounted on the mount board. Also, gaps with a large volume may be formed in an area where the columnar conductors are not arranged at a high density. This can improve the connection strength between the columnar conductors and the mount board.

An electronic apparatus according to the present invention includes the module and a mount board having the module mounted thereon. The mount board is disposed adjacent to the other end of the columnar conductor, and the mount board and the columnar conductor are connected to each other via solder. Since the mount board and the columnar conductor are connected as described above, it is possible to provide the electronic apparatus where the module and the mount board are connected to each other with high reliability.

A method for manufacturing a module according to the present invention includes a preparing step of preparing a wiring board on which a component is mounted and to which one end of a columnar conductor for external connection is connected, the columnar conductor having an outer periphery coated with a coating material at the other end thereof, the coating material being made of a material having a melting point lower than that of solder; a resin layer forming step of forming a resin layer on the wiring board, the resin layer being configured to cover the component and the columnar conductor; and an exposure step of grinding the resin layer to cause the other end of the columnar conductor and the coating material to be exposed from a surface of the resin layer.

Before the columnar conductor is covered by the resin layer, in the preparing step, the outer periphery of the other end portion of the columnar conductor is coated with the coating material made of a material having a melting point lower than that of solder. Thus, during the connection of the module to the external mount board, the coating material is volatilized or eluted to form a gap between the resin layer and the outer periphery of the other end portion of the columnar conductor. It is thus possible to manufacture the module that can achieve a highly reliable connection to the external mount board.

Until the module is connected to the external mount board, the gap is filled with the coating material. Therefore, it is possible to manufacture the module that can prevent dust and impurities from entering the gap before the module is mounted on the mount board.

The melting point of the material of the coating material may be lower than the melting point of solder, and lower than a curing temperature of the resin of the resin layer. With this configuration, in the resin layer forming step, the coating material is volatilized or eluted to form the gap between the resin layer and the outer periphery of the other end portion of the columnar conductor. It is thus possible to reliably form the gap.

The material of the coating material may be wax, brazing filler metal, or flux. In this case, wax, brazing filler metal, or flux may be used as the coating material for forming the gap.

In the present invention, the gap is formed between the resin layer and at least part of the periphery of the other end portion of the columnar conductor. Thus, not only the end face of the columnar conductor at the other end thereof but also the at least part of the periphery of the other end portion of the columnar conductor is exposed without being covered with resin of the resin layer. Both the end face of the columnar conductor and the periphery of the columnar conductor exposed to the gap, at the other end of the columnar conductor, serve as a connection surface for connection to the external mount board. This makes the connection area greater than that in the case where the module is connected to the mount board only at the end face of the columnar conductor at the other end thereof, and thus improves the connection strength between the module and the mount board. Therefore, without the external connection terminals provided in the related art to ensure the connection strength and connection reliability, it is possible to provide the module that has a highly reliable connection to the mount board.

Other features, elements, characteristics and advantages of the present invention will become more apparent from the following detailed description of preferred embodiments of the present invention with reference to the attached drawings.

### BRIEF DESCRIPTION OF THE SEVERAL VIEWS OF THE DRAWINGS

FIG. 1 is a cross-sectional view of an electronic apparatus in which a module according to a first embodiment of the present invention is mounted on a mount board;

FIG. 2 is a bottom view of the module illustrated in FIG. 1;

FIGS. 3A to 3E are diagrams for describing a method for manufacturing the module illustrated in FIG. 1;

FIG. 4 illustrates a modification of gaps to be filled with solder;

FIG. 5 is a cross-sectional view of an electronic apparatus in which a module according to a second embodiment of the present invention is mounted on the mount board; and

FIG. 6 is a cross-sectional view of a module of related art.

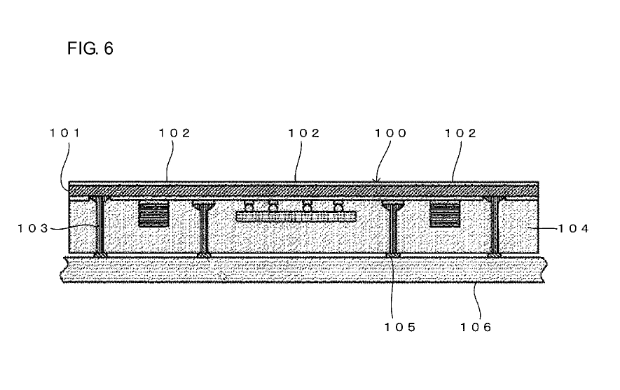

### DETAILED DESCRIPTION OF THE INVENTION

### First Embodiment

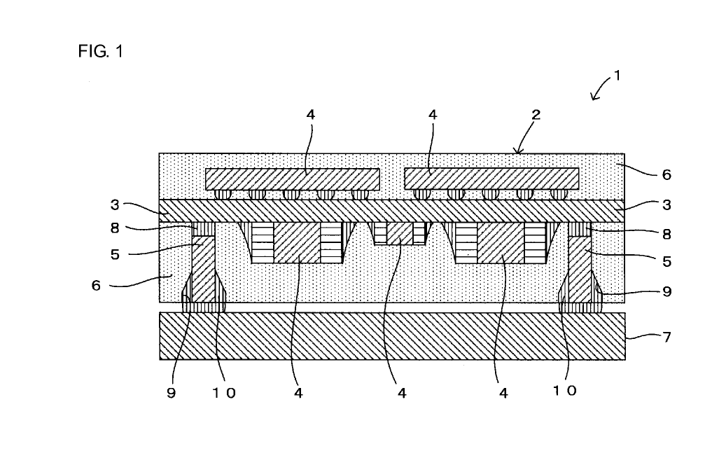

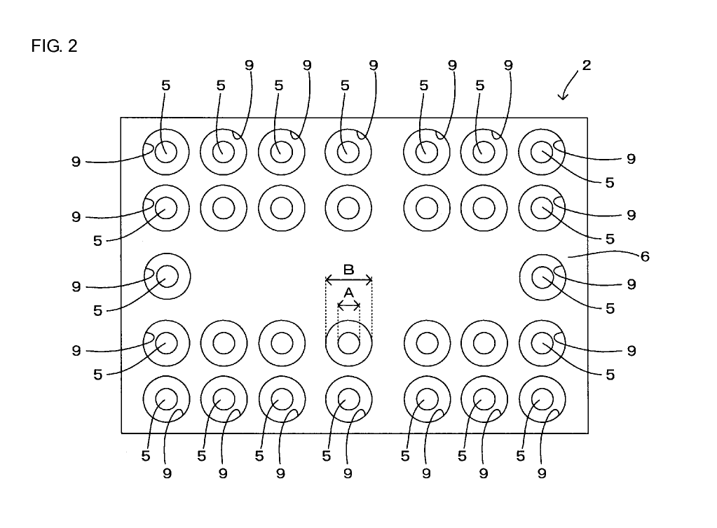

An electronic apparatus 1 including a module 2 according to a first embodiment of the present invention will be described with reference to FIGS. 1 and 2. FIG. 1 is a cross-sectional view of the electronic apparatus 1 according to the first embodiment, and FIG. 2 is a bottom view of the module 2 illustrated in FIG. 1.

The electronic apparatus 1 according to the first embodiment includes the module 2 and a mount board 7 on which the module 2 is mounted. First, the module 2 will be described.

The module 2 forms a part of the electronic apparatus 1 in which the electric circuits are formed. Specifically, the module 2 includes a wiring board 3; a plurality of components 4 mounted on the front and back surfaces of the wiring board 3; a plurality of columnar conductors 5 for external connection, the columnar conductors 5 each being connected at one end thereof to the wiring board 3; and a resin layer 6 disposed on the wiring board 3 and configured to cover the columnar conductors 5 and the components 4. The module 2 is mounted on the external mount board 7 by means of solder, which is an example of a conductive member. The conductive member used to mount the module 2 on the mount board 7 is not limited to solder. For example, a conductive adhesive may be used to mount the module 2 on the mount board 7.

The wiring board 3 is formed, for example, by a glass epoxy resin substrate, a low-temperature co-fired ceramic (LTCC) substrate, or a glass substrate. Wiring electrodes and via conductors (not shown) are formed on principal surfaces of, and inside, the wiring board 3. The wiring board 3 may be either a multi-layer substrate or a single-layer substrate.

The components 4 include active components, such as semiconductor elements, and passive components, such as chip capacitors, chip inductors, and chip resistors. The components 4 are mounted on both the principal surfaces of the wiring board 3 using a known surface mount technology. The components 4 may be mounted on only one principal surface of the wiring board 3. The total number of the components 4 may be changed appropriately depending on the circuit configuration of the module 2.

Each of the columnar conductors 5 is a pin-like conductor (substantially cylindrically-shaped in the present embodiment) formed by shearing a wire rod made of a conductive material, such as copper (Cu). The columnar conductors 5 are each connected at one end thereof to a mounting electrode 8 on the lower principal surface of the wiring board 3 by means of solder or the like, and connected at the other end thereof to the external mount board 7 by solder 10. For example, the outer surface of each columnar conductor 5 may be gold (Au)-plated. This improves the wettability of the solder 10.

The resin layer 6 is made of a thermosetting resin, such as epoxy resin. The resin layer 6 is disposed on each principal surface of the wiring board 3 to cover the components 4 and the columnar conductors 5. To connect the module 2 to the mount board 7, the resin layer 6 covers the columnar conductors 5 and the components 4, with an end face of each columnar conductor 5 at the other end thereof exposed from a surface of the resin layer 6. A gap 9 to be filled with solder is formed between the resin layer 6 and a periphery of the other end portion of each columnar conductor 5. Specifically, as illustrated in FIG. 1, each gap 9 defined by the columnar conductor 5 and the resin layer 6 is formed such that the distance between the columnar conductor 5 and the resin layer 6 becomes smaller from the other end to the one end of the columnar conductor 5. At the same time, as illustrated in FIG. 2, each gap 9 has a substantially annular contour as viewed from the bottom of the module 2. The resin layer 6 may be made of thermoplastic resin, such as polyimide.

By forming the gaps 9 to be filled with solder as described above, the end face of each columnar conductor 5 at the other end thereof and the periphery of the other end portion of the columnar conductor 5 are exposed without being covered by the resin layer 6, and both the end face and the periphery of the columnar conductor 5 function as a connection surface for mounting the module 2 to the mount board 7.

Each of the columnar conductors 5 in the present embodiment has a diameter A (see FIG. 2) of about 300 μm. If a principal surface of a land electrode (not shown) on the mount board 7 connected to the corresponding columnar conductor 5 is substantially square in shape, the length of one side of the land electrode is about 500 μm, which is about 200 μm greater than the diameter A of the columnar conductor 5. Therefore, among the substantially annular contour of each of the gaps 9, it is preferable that a diameter B (see FIG. 2) of the outer circle formed by the resin layer 6 is about 500 μm. Thus, the gaps 9 are each formed to have an appropriate size which does not prevent high-density mounting of the columnar conductors 5.

The gaps 9 each do not necessarily have to be formed between the resin layer 6 and the entire periphery of an end portion of the columnar conductor 5 at the other end thereof, and may be formed between the resin layer 6 and at least part of the periphery of the end portion of the columnar conductor 5.

Alternatively, for example, the volume of each gap 9 formed where the columnar conductors 5 are arranged with a narrow pitch may be smaller than that of each gap 9 formed in other areas. That is, there may be some gaps 9 having a different volume.

Before the module 2 is mounted on the mount board 7, each gap 9 may be filled with a material having a melting point lower than that of solder so as to prevent dust and impurities from entering the gap 9.

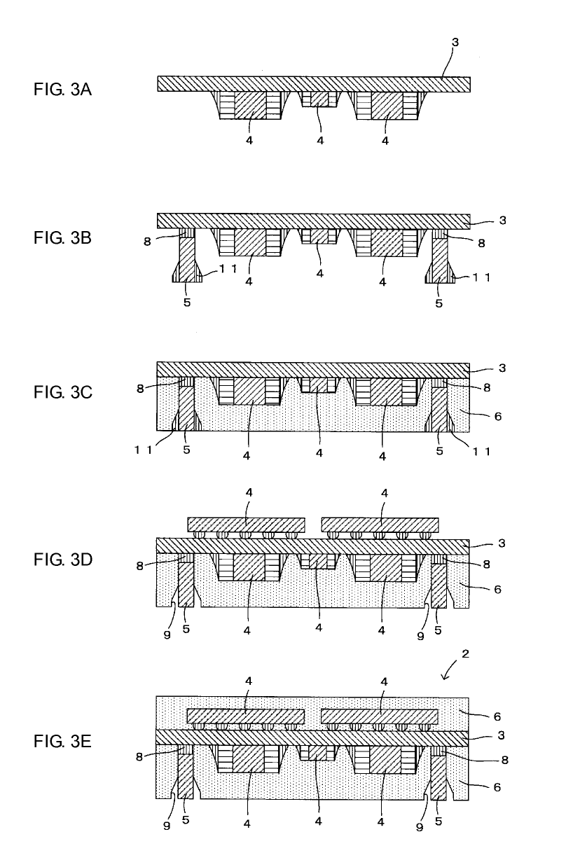

Next, a method for manufacturing the module 2 will be described with reference to FIGS. 3A to 3E. FIGS. 3A to 3E are diagrams for describing a method for manufacturing the module 2. Specifically, FIGS. 3A to 3E each illustrate a step of the method for manufacturing the module 2.

First, as illustrated in FIG. 3A, the components 4, such as chip capacitors and chip inductors, are mounted on one principal surface of the wiring board 3 using a known surface mount technology. Together with (or instead of) the chip capacitors and the chip inductors, semiconductor elements, such as ICs, may be mounted on the wiring board 3 as the components 4. Note that wiring electrodes and via conductors are formed in advance on both the principal surfaces of, and inside, the wiring board 3.

Next, as illustrated in FIG. 3B, the columnar conductors 5 made of a conductive material, such as Cu, are mounted on the one principal surface of the wiring board 3 by connecting one ends of the columnar conductors 5 to the respective mounting electrodes 8 formed on the one principal surface of the wiring board 3. Then, through the use of a transfer method or a dipping method, the columnar conductors 5 are each coated, at the other end thereof, with a coating material 11 made of wax, brazing filler metal, flux, oil, or the like having a melting point lower than that of solder. The steps of mounting the components 4 and the columnar conductors 5 on the wiring board 3 illustrated in FIGS. 3A and 3B correspond to a preparing step according to the present invention. In the steps described below, flux is used as the coating material 11.

After epoxy resin is applied to cover the components 4 and the columnar conductors 5 mounted on the one principal surface of the wiring board 3, the epoxy resin is cured to form the resin layer 6 (the resin layer forming step). The epoxy resin is cured at a temperature of about 180° C. The resin layer 6 may be formed by a compression molding method, a transfer molding method, a printing method, or various other methods.

Next, as illustrated in FIG. 3C, the other ends of the columnar conductors 5 and the coating materials 11 are exposed from a surface of the resin layer 6 by grinding the resin layer 6 (the exposure step).

Next, as illustrated in FIG. 3D, semiconductor elements (ICs) are mounted as the components 4 on the other principal surface of the wiring board 3. Since the melting point of the coating materials 11 is lower than that of solder, the coating materials 11 are volatilized or eluted from the resin layer 6 during mounting of the components 4. This forms the gap 9 between the resin layer 6 and the periphery of an end portion of each columnar conductor 5 at the other end thereof. Alternatively, the columnar conductors 5 may be mounted on the one principal surface of the wiring board 3 after the components 4 are mounted on both the principal surfaces of the wiring board 3. In this case, the gaps 9 are formed when the module 2 is mounted on the mount board 7.

When brazing filler metal or wax is used as the coating materials 11, since their melting points are lower than a curing temperature of the resin of the resin layer 6, the gap 9 is formed between the resin layer 6 and the periphery of the end portion of each columnar conductor 5 when the coating materials 11 are volatilized or eluted from the resin layer 6 during formation of the resin layer 6. In this case, after the exposure step, the formed gaps 9 may be filled with the coating materials 11 again by applying brazing filler metal or wax to the gaps 9.

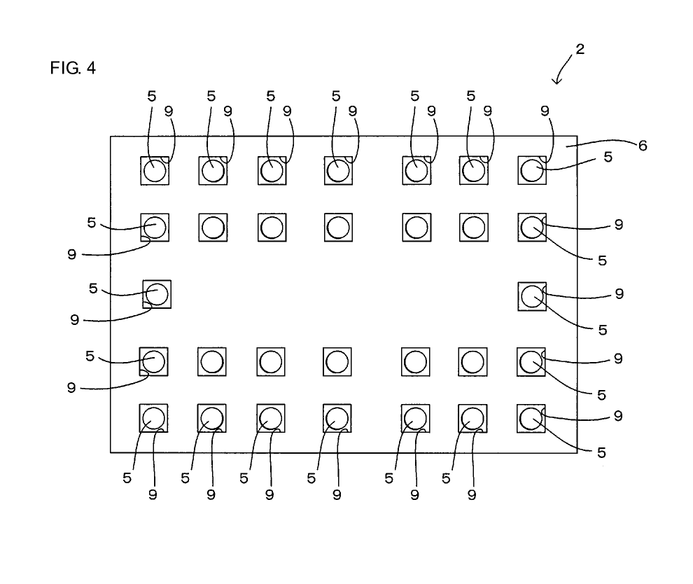

Alternatively, the gaps 9 may be formed after the exposure step by irradiating, with laser, an area around the end face of each columnar conductor 5 at the other end thereof exposed from the surface of the resin layer 6. When the gaps 9 are formed using laser, the contour of each gap 9 in the resin layer 6 may be formed in a substantially square shape as viewed from the bottom of the module 2 (as in FIG. 4 illustrating a modification of the gaps 9), so as to fit the shape (substantially square) of land electrodes on the mount board 7. After the formation, the gaps 9 may be filled with brazing filler metal, wax, flux, or the like.

Next, as illustrated in FIG. 3E, after the resin is applied to cover the components 4 mounted on the other principal surface of the wiring board 3, the resin layer 6 is also formed on the other principal surface of the wiring board 3 by curing the resin, and thus the module 2 is manufactured.

The mount board 7 is placed on one side of the module 2 adjacent to the other ends of the columnar conductors 5. Then, the end portions of the columnar conductors 5 at the other ends thereof are connected by means of the solder 10 to the mount board 7 to manufacture the electronic apparatus 1. The solder 10 melted during this connection process is interposed between the mount board 7 and the end face of each columnar conductor 5 at the other end thereof. At the same time, part of the solder 10 enters each gap 9 and contacts the periphery of the other end portion of the columnar conductor 5 exposed from the resin layer 6. Then, the conductor (e.g., Cu) of the end face and the periphery of the columnar conductor 5 at the other end thereof and the solder 10 interdiffuse to form an intermetallic compound, and thus the module 2 and the mount board 7 are connected to each other.

In the embodiment described above, the gap 9 to be filled with solder is formed between the resin layer 6 and the periphery of the other end portion of each columnar conductor 5. Therefore, not only the end face but also the periphery of the columnar conductor 5 at the other end thereof is exposed without being covered with resin of the resin layer 6. The end face of the columnar conductor 5 at the other end thereof and the periphery of the columnar conductor 5 exposed to the gap 9 serve as a connection surface for connection to the external mount board 7. This makes the connection area between the module 2 and the mount board 7 greater than that in the case where the module 2 is connected to the mount board 7 only at the end face of each columnar conductor 5 at the other end thereof, and thus improves the connection strength between the module 2 and the mount board 7. Therefore, without the external connection terminals provided in the related art to ensure the connection strength and connection reliability, it is possible to provide the module 2 that has a highly reliable connection to the mount board 7. Additionally, since each columnar conductor 5 having the end face and the periphery at the other end thereof exposed from the resin layer 6 is connected by means of solder to the mount board 7, it is possible to provide the electronic apparatus 1 where the module 2 and the mount board 7 are connected to each other with high reliability.

Unlike the module of the related art, it is not necessary to add an external connection terminal to the end face of each columnar conductor 5. This can lower the profile of the module 2 and reduce the cost of manufacture.

Before the module 2 is mounted on the mount board 7, if each gap 9 is filled with the coating material 11 made of wax, brazing filler metal, or the like having a melting point lower than that of the solder 10, it is possible to prevent dust and impurities from entering the gap 9 until the module 2 is mounted on the mount board 7 since each gap 9 is filled with the coating material 11. During the connection of the module 2 to the mount board 7, the coating material 11 is volatilized or melted by heating and moved out of each gap 9. Thus, since the solder can spread out within the gap 9 during the connection, the module 2 can be smoothly connected to the mount board 7.

The gaps 9 allow both the end face and the periphery of each columnar conductor 5 at the other end thereof to be exposed from the resin layer 6. This improves the heat dissipation characteristics of the module 2.

Increasing the connection area between the columnar conductors 5 of the module 2 and the mount board 7 increases the amount of the solder 10 used for the connection. This improves a self-alignment effect for mounting the module 2 on the mount board 7. Also, increasing the connection area described above prevents poor wetting of the solder 10 during mounting of the module 2.

As described above, the volume of each gap 9 formed in an area where the columnar conductors 5 are arranged at a high density may be made smaller than that of each gap 9 in other areas. This can prevent the solder 10 in each gap 9 formed in an area where the columnar conductors 5 are arranged at a high density from flowing between adjacent columnar conductors 5 and causing these columnar conductors 5 to be short-circuited. Also, it is possible to increase the volume of each gap 9 formed in areas where the columnar conductors 5 are not arranged at a high density, and to improve the connection strength between the module 2 and the mount board 7.

In the process of manufacturing the module 2 illustrated in FIGS. 3A to 3E, the gaps 9 can be formed by a simple method in which the other ends of the columnar conductors 5 are coated with the coating materials 11, and the resin layer 6 is polished or ground to cause the other ends of the columnar conductors 5 and the coating materials 11 to be exposed from the surface of the resin layer 6. This facilitates the manufacture of the module 2 having a highly reliable connection to the external mount board 7. The gaps 9 are formed as described above. Therefore, unlike the module of the related art, it is not necessary to provide external connection terminals to ensure the strength of connection to the mount board 7. The module 2 having a low profile can thus be manufactured.

### Second Embodiment

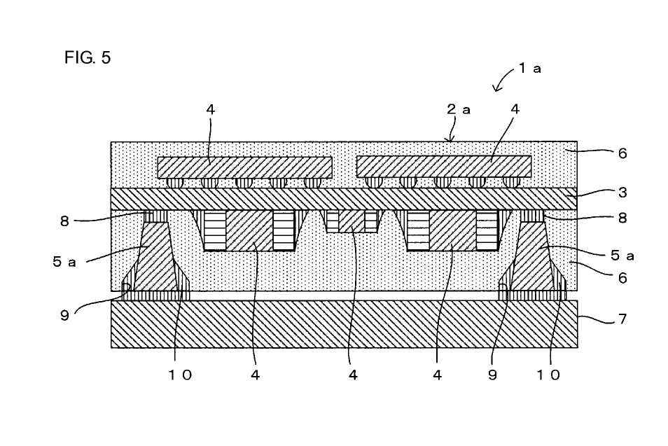

A module 2a according to a second embodiment of the present invention will be described with reference to FIG. 5. FIG. 5 is a cross-sectional view of an electronic apparatus 1a in which the module 2a is mounted on the mount board 7.

As illustrated in FIG. 5, the module 2a of the second embodiment differs from the module 2 of the first embodiment described with reference to FIG. 1 in that each of columnar conductors 5a is tapered, that is, the diameter of each columnar conductor 5a decreases from the other end to the one end of the columnar conductor 5a. The other components of the second embodiment are the same as those of the first embodiment, and their description will be omitted by giving the same reference numerals thereto.

A method for manufacturing the module 2a differs from the method for manufacturing the module 2 of the first embodiment described with reference to FIGS. 3A to 3E, in terms of the method for forming the columnar conductors 5a. Specifically, after the components 4 are mounted on both principal surfaces of the wiring board 3, the resin layer 6 is formed on each of the principal surfaces of the wiring board 3 to cover the components 4. Next, recesses for the gaps 9 are formed, by means of laser, in the surface of the resin layer 6 on one principal surface (lower in FIG. 5) of the wiring board 3. Each of the recesses is filled with the coating material 11.

Next, in the same manner as that for forming via conductors in the related art, the interior of each recess is irradiated with laser to form a hole in the resin layer 6 until the mounting electrode 8 on the wiring board 3 is exposed. Then, the hole is filled with a conductor, such as Cu or silver (Ag), to form each columnar conductor 5a, and thus the module 2a is manufactured. The hole for each columnar conductor 5a is tapered.

Before recesses for the gaps 9 are formed, holes may be formed in the resin layer 6 by means of laser, and each columnar conductor 5a may be formed by filling each of the holes with a conductor. Then, the recess for each gap 9 is formed, by means of laser, around the end face of the columnar conductor 5a exposed from the surface of the resin layer 6, and the recess is filled with the coating material 11.

Another method for forming the gaps 9 may be to use a resin having a high heat shrinkage ratio. For example, when a resin having a high heat shrinkage ratio is applied to the wiring board 3, with one principal surface of the wiring board 3 for arranging the columnar conductors 5a thereon facing upward, a filler contained in the resin is precipitated and accumulated on the one principal surface side of the wiring board 3 during curing of the resin. This makes the surface of the resin layer 6 coarse. Then, the resulting recesses in the coarse surface of the resin layer 6 are used for the gaps 9, and form the gaps 9. In this case, after the resin of the resin layer 6 is cured, the recesses in the surface of the resin layer 6 may be filled with the coating materials 11, and the columnar conductors 5a may be formed by means of laser.

To reduce heat shrinkage of resin, the resin layer 6 may have a two-layer structure which is composed of a resin layer made of a resin with a low heat shrinkage ratio, and a resin layer made of a resin with a high heat shrinkage ratio and disposed on the surface side of the resin layer 6. To minimize gaps inside the resin layer 6 in the case of forming the resin layer 6 only of a resin with a high heat shrinkage ratio, for example, half of the resin may be first applied to the wiring board 3 and cured. Then, the remaining half of the resin is applied to fill in irregularities in the coarse surface of the cured resin layer, and thus to form the resin layer 6. In this case, it is possible to form the gaps 9 in the surface of the resin layer 6 while reducing voids inside the resin layer 6.

In the second embodiment, the columnar conductors 5a are each tapered as described above. This can increase the area of the end face of each columnar conductor 5a at the other end thereof, the end face being exposed from the surface of the resin layer 6. Therefore, it is possible to increase the area of connection between the module 2a and the mount board 7, and improve the strength of connection between the module 2a and the mount board 7.

The present invention is not limited to the embodiments described above, and various changes other than those described above may be made to the present invention without departing from the scope thereof.

For example, in the embodiments described above, as illustrated in FIGS. 1 and 5, the resin layer 6 is flush with the end face of each of the columnar conductors 5 or 5a at the other end thereof. However, the end portion of each of the columnar conductors 5 or 5a at the other end thereof may protrude from the surface of the resin layer 6.

Another method for forming the gaps 9 may be one in which, after a water repellent, such as silicone resin or fluorocarbon resin, is applied to the other end of each columnar conductor 5, one end of each columnar conductor 5 is connected to the wiring board 3. This is followed by forming the resin layer 6, and removing the water repellent to form the gaps 9. Another method for forming the gaps 9 may be one in which, after polyamide or the like soluble in an alcohol solvent is applied to the other end of each columnar conductor 5, one end of each columnar conductor 5 is connected to the wiring board 3. This is followed by forming the resin layer 6, and removing the polyamide with alcohol or the like to form the gaps 9. When holes for columnar conductors are formed by means of laser after the resin layer 6 is formed, the holes may be made in a large size to allow space to be turned into the gaps 9.

The present invention is applicable to various modules externally connected by means of columnar conductors.

While preferred embodiments of the invention have been described above, it is to be understood that variations and modifications will be apparent to those skilled in the art without departing from the scope and spirit of the invention. The scope of the invention, therefore, is to be determined solely by the following claims.

What is claimed is:

1. A module externally connected by means of a conductive member, the module comprising:
a wiring board;
a component mounted on the wiring board;
a columnar conductor for external connection, one end of the columnar conductor being connected to the wiring board; and
a resin layer disposed on the wiring board and covering the columnar conductor and the component except that an end face of other end of the columnar conductor and at least a part of a periphery of the columnar conductor located at a side proximate to the other end are not covered with the resin layer to form a gap between the resin layer and the part of the periphery of the columnar conductor.

2. The module according to claim 1, wherein the conductive member is solder; and
the gap is filled with a material having a melting point lower than a melting point of the solder.

3. The module according to claim 1, wherein the columnar conductor includes a first columnar conductor and a second columnar conductor; and
a volume of the gap between the resin layer and the first columnar conductor differs from a volume of the gap between the resin layer and the second columnar conductor.

4. An electronic apparatus comprising:
the module according to claim 1; and
a mount board having the module mounted thereon,
wherein the mount board is disposed adjacent to the other end of the columnar conductor, and the mount board and the columnar conductor are connected to each other via solder.

5. A method for manufacturing a module, comprising:
a preparing step of preparing a wiring board on which a component is mounted and to which one end of a columnar conductor for external connection is connected, an outer periphery of the columnar conductor located at a side proximate to the other end being coated with a coating material, the coating material being made of a material having a melting point lower than a melting point of solder;
a resin layer forming step of forming a resin layer on the wiring board, the resin layer covering the component and the columnar conductor; and
an exposure step of grinding the resin layer to expose the other end of the columnar conductor and the coating material from a surface of the resin layer.

6. The method according to claim 5, wherein the melting point of the material of the coating material is lower than the melting point of solder, and lower than a curing temperature of the resin of the resin layer.

7. The method according to claim 5, wherein the material of the coating material is wax, brazing filler metal, or flux.

8. The module according to claim 2, wherein the columnar conductor includes a first columnar conductor and a second columnar conductor; and
a volume of the gap between the resin layer and the first columnar conductor differs from a volume of the gap between the resin layer and the second columnar conductor.

9. An electronic apparatus comprising:
the module according to claim 2; and
a mount board having the module mounted thereon,
wherein the mount board is disposed adjacent to the other end of the columnar conductor, and the mount board and the columnar conductor are connected to each other via solder.

10. An electronic apparatus comprising:
the module according to claim 3; and
a mount board having the module mounted thereon,
wherein the mount board is disposed adjacent to the other end of the columnar conductor, and the mount board and the columnar conductor are connected to each other via solder.

11. The method according to claim 6, wherein the material of the coating material is wax, brazing filler metal, or flux.
